(19) United States
(12) Patent Application Publication
(10) Pub. No.: US 2014/0361737 A1
(43) Pub. Date: Dec. 11, 2014

(54) DISPLAY AND ELECTRONIC DEVICE ADAPTED TO THE DISPLAY

(71) Applicant: HON HAI PRECISION INDUSTRY CO., LTD., New Taipei (TW)

(72) Inventor: KUANG-YAO LIAO, New Taipei (TW)

(21) Appl. No.: 14/295,529

(22) Filed: Jun. 4, 2014

(30) Foreign Application Priority Data
Jun. 6, 2013 (TW) 102120023

(51) Int. Cl. H02J 7/02; H05K 9/00; H05K 5/00

(52) U.S. Cl. CPC H02J 7/025; H05K 5/0017; H05K 9/0007
USPC 320/108

(57) ABSTRACT

A display able to recharge a battery of a portable device in close proximity includes a transparent layer, a displaying layer, a transmitting module, and a back shroud. The displaying layer is attached to the transparent layer. The transmitting module includes a transmitting coil attached to the displaying layer and a shielding layer shielding the transmitting coil and attached to the displaying layer. The back shroud houses the transmitting module and the displaying layer, and is attached to the transparent layer. The transmitting coil is configured for outputting electromagnetic waves to a receiving coil of an electronic device, causing the receiving coil to charge the electronic device. The instant application further provides an electronic device adapted to the display.

### FIELD

1. Field

The subject matter herein generally relates to displays and an electronic device electrically adapted to a display.

2. Background

An electronic device such as mobile phone can be equipped with a rechargeable battery. When the battery is exhausted, the electronic device can be recharged.

### BRIEF DESCRIPTION OF THE DRAWING

Implementations of the present technology will now be described, by way of example only, with reference to the attached figures, wherein:

FIG. 1 is a perspective view of an embodiment of a display and an electronic device adapted to the display, the display includes a back shroud.

FIG. 2 is a partial elevational view of the display of FIG. 1, with the back shroud removed.

FIG. 3 is a rear elevational view of the display of FIG. 1.

FIG. 4 is a partial elevational view of the electronic device of FIG. 1.

FIG. 5 is a charging drive circuit of the display and the electronic device of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that is modified, such that the feature of the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

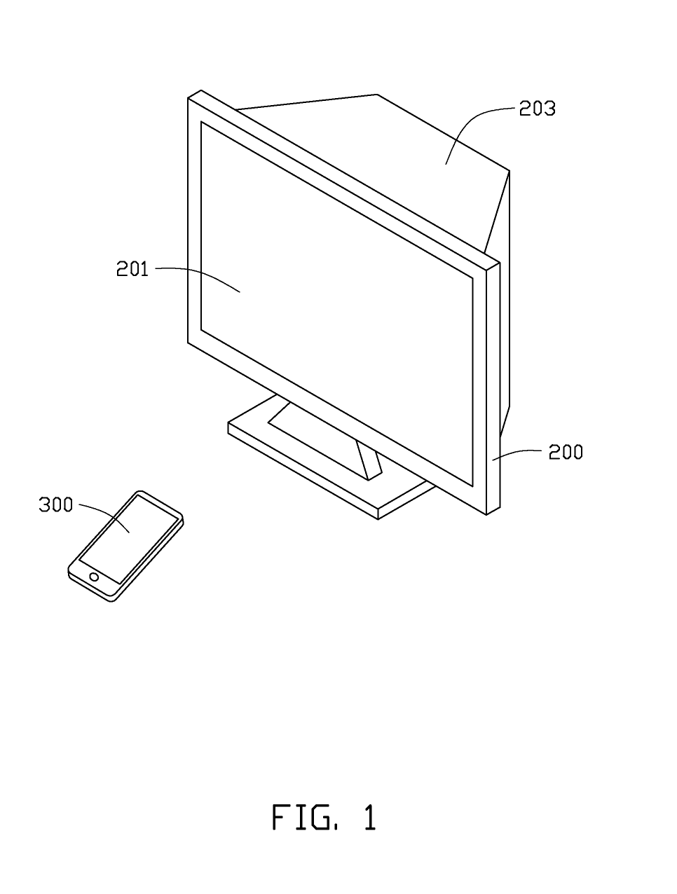

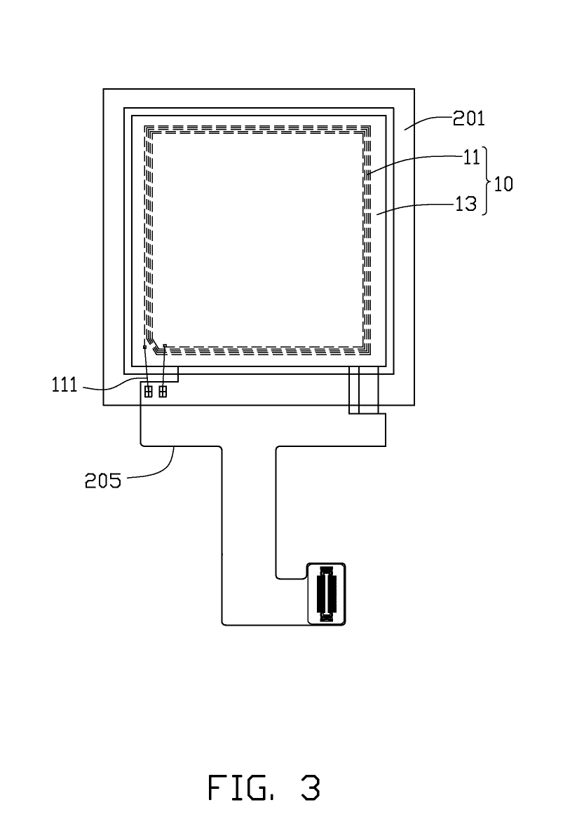

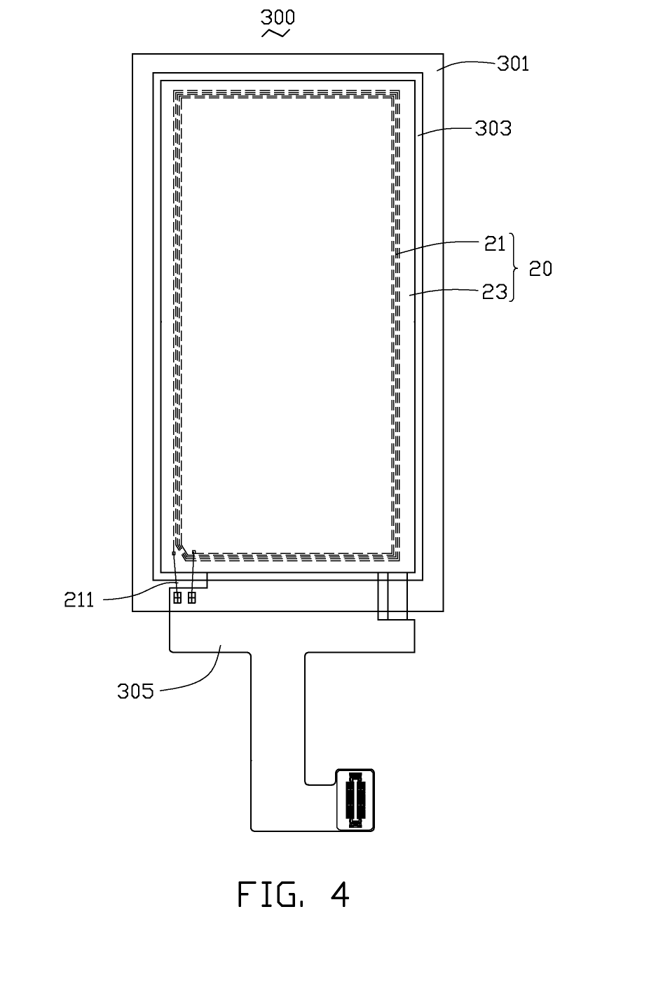

FIG. 1 illustrates a wireless charging system can include a display 200 and a receiving module 20 (see FIG. 4) employed in an electronic device 300. The display 200 can include a transmitting module 10 (see FIG. 3). The electronic device 300 can be located adjacent to the display 200. The receiving module 20 can be configured to receive electrical power from the transmitting module 10 automatically to charge the electronic device 300.

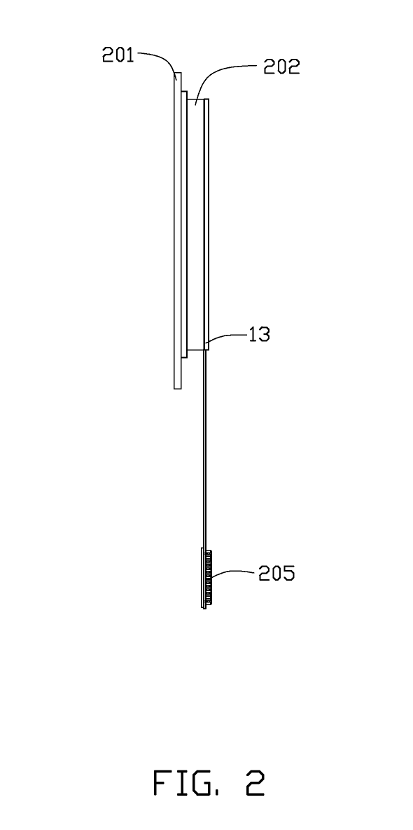

FIG. 2 illustrates the display 200 including a transparent layer 201, a displaying layer 202, and a back shroud 203 (see FIG. 1) located at a back of the display 200. The transparent layer 21 can be made of glass materials. The displaying layer 202 can be adhered to a back of the transparent layer 201 for illumination and displaying. The displaying layer 202 can be equipped with circuit connecting pins 205. Referring to FIG. 3, the transmitting module 10 can be attached to a side of the displaying layer 202 away from the transparent layer 201, and can include a transmitting coil 11 and a shielding layer 13. The transmitting coil 11 and the shielding layer 13 can be arranged on the displaying layer 202 in that order. The shielding layer 13 can shield the transmitting coil 11 and is attached to the displaying layer 202. The transmitting coil 11 can be sandwiched between the displaying layer 202 and the shielding layer 13. In an example, the shielding layer 13 can be substantially a square flexible plate.

The transmitting coil 11 can include many turns of windings, and an outer contour of the transmitting coil 11 can be substantially square, for example, substantially in a “ [symbol] ” shape. A size of a periphery of the transmitting coil 11 can be less than that of the shielding layer 13. The transmitting coil 11 can be attached to the displaying layer 202 by electroplating or soldering, and attached to a side of the displaying layer 202 away from the transparent layer 21. The transmitting coil 11 can be configured for outputting electromagnetic waves, and can be equipped with FPC (flexible printed circuit) connecting pins 111. The FPC connecting pins 111 can be electrically coupled to the circuit connecting pins 205 of the displaying layer 202 and coupled to a circuit board (not shown) of the display 200. The back shroud 203 can house the displaying layer 202 and the transmitting layer coil 11, and can be peripherally attached to the transparent layer 201. The back shroud 203 can be equipped with metallic members (not shown). The transparent layer 201 can be made of resin materials. In the embodiment, the display 200 can be the display of a desktop computer.

FIG. 4 illustrates some components of the electronic device 300 equivalent to those of the display 200. The display 200 can include a transparent layer 301 and a displaying layer 303 attached to a back of the transparent layer 301. The displaying layer 303 can be equipped with circuit connecting pins 305. The receiving module 20 can be attached to a side of the displaying layer 303 away from the transparent layer 301, and can include a receiving coil 21 and a shielding layer 23. The receiving coil 21 and the shielding layer 23 can be arranged on the displaying layer 303 in that order. The shielding layer 23 can shield the receiving coil 21 and be attached to the displaying layer 303. The receiving coil 21 can be sandwiched between the displaying layer 303 and the shielding layer 23, and configured to receive the electromagnetic waves output from the display 300. In an example, the receiving coil 21 can include multiple turns of windings, and an outer contour of the receiving coil 21 can be substantially square, for example, in “ [symbol] ” shape. A peripheral size of the receiving coil 21 can be less than that of the shielding layer 23. The receiving coil 21 can be attached to the displaying layer 303 by electroplating or soldering, and attached to a side of the displaying layer 303 away from the transparent layer 301. The receiving coil 21 can be equipped with FPC connecting pins 211. The FPC connecting pins 211 can be coupled to the circuit connecting pins 305 of the displaying layer 303 and coupled to a circuit board (not shown) of the electronic device 300. The transparent layer 201 may be made of resin materials. In the embodiment, the electronic device 300 can be a mobile phone.

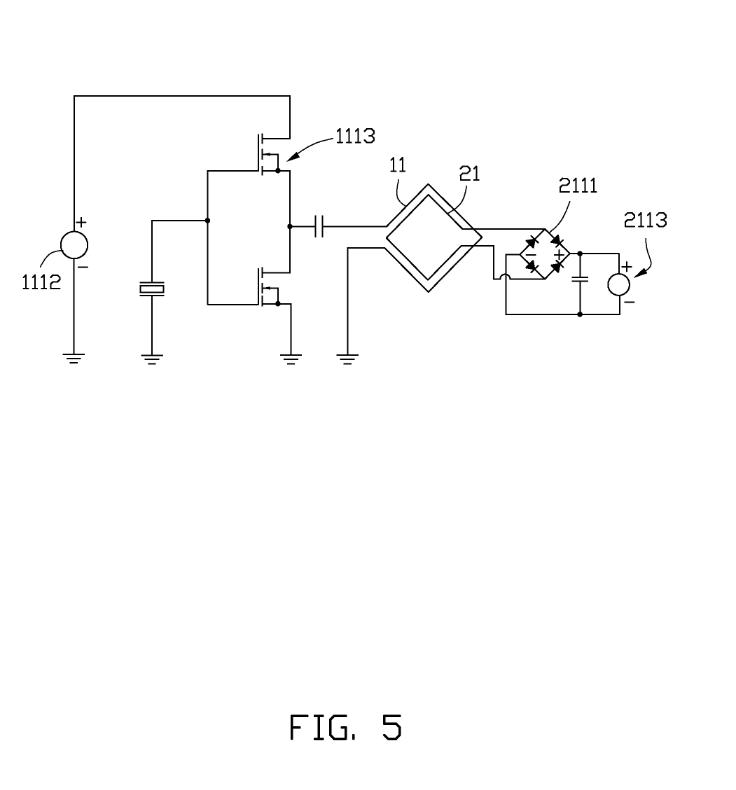

FIG. 5 shows that the emitting module 10 can further include DC (direct current) input terminals 1112 and a resonator 1113. The DC input terminals 1112 can be electrically coupled to the FPC connecting pins 111 and configured for taking electrical power from the circuit board of the display 200. The resonator 1113 can be electrically coupled to the DC input terminals 1112 and the transmitting coil 11 and configured to convert direct current into alternating current, to supply the transmitting coil 11. The receiving module 10 can further include a commutator 2111 and DC (direct current) output terminals 2113. The DC output terminals 2113 can be electrically coupled to the FPC connecting pins 211 and configured for charging the electronic device 300. The commutator 2111 can be electrically coupled to the DC output terminals 2113 and the receiving coil 21 and configured for converting alternating current into direct current to supply the DC output terminals 2113.

When in use, the electronic device 300 can be located adjacent to the display 200, such that the electronic device 300 faces the display 200 and a distance between them is less than 1 meter. The transmitting coil 11 can radiate electromagnetic waves of a predetermined frequency, the receiving module 20 can receive the electromagnetic waves and can convert it into direct current to charge the electronic device 300.

The electronic device 300 is not necessary limited to a mobile phone, it may be a wireless mouse, a wireless earphone, a remote controller, and so on, the electronic device 300 need only contain a receiving module 20. The shielding layer 13 may have a shape the same as the transmitting coil 11 for shielding a back of the transmitting coil 11. The shielding layer 23 may have a shape the same as the receiving coil 21 for shielding a back of the receiving coil 11.

The embodiments shown and described above are only examples. Many details are often found in the art such as the other features of a display and an electronic device adapted to the display. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A display comprising:
a transparent layer;
a displaying layer attached to the transparent layer;
a transmitting module comprising:
a transmitting coil attached to the displaying layer; and
a shielding layer shielding the transmitting coil and attached to the displaying layer; and
a back shroud housing the transmitting module and the displaying layer, and attached to the transparent layer, wherein the transmitting coil is configured for outputting electromagnetic wave to a receiving coil of an electronic device, causing the receiving coil to charge the electronic device.

2. The display of claim 1, wherein the transmitting coil is attached to the displaying layer by electroplating or soldering, and sandwiched between the displaying layer and the shielding layer.

3. The display of claim 1, wherein the shielding layer is a flexible board, a size of a periphery of the transmitting coil is less than that of the shielding layer.

4. The display of claim 1, wherein the transmitting coil comprises many turns of windings, and an outer contour of the transmitting coil is substantially a “ [symbol] ” shape, the shielding layer is substantially in a “ [symbol] ” shape corresponding to the transmitting coil and covers the transmitting coil.

5. The display of claim 1, wherein the transmitting coil is equipped with a flexible printed circuit connecting pin, the displaying layer is equipped with a circuit connecting pin electrically coupled to the flexible printed circuit connecting pin.

6. An electronic device adapted to the display of claim 1, comprising
a transparent layer;
a displaying layer attached to the transparent layer of the electronic device;
a receiving module, comprising:
a receiving coil attached to the displaying layer; and
a shielding layer shielding the receiving coil and attached to the displaying layer of the electronic device,
wherein the receiving coil is configured for receiving electromagnetic wave from the transmitting coil of the display and charging the electronic device.

7. The electronic device of claim 6, wherein the receiving coil is attached to the displaying layer of the electronic device by electroplating or soldering, and sandwiched between the displaying layer of the electronic device and the shielding layer of the electronic device.

8. The electronic device of claim 6, wherein the shielding layer of the electronic device is a flexible board, a size of a periphery of the receiving coil is less than that of the shielding layer of the electronic device.

9. The electronic device of claim 6, wherein the receiving coil comprises many turns of windings, and an outer contour of the receiving coil is substantially a “ [symbol] ” shape, the shielding layer of the electronic device is substantially in a “ [symbol] ” shape corresponding to the receiving coil and covers the receiving coil.

10. The electronic device of claim 6, wherein the receiving coil is equipped with a flexible printed circuit connecting pin, the displaying layer of the electronic device is equipped with a circuit connecting pin electrically coupled to the flexible printed circuit connecting pin of the receiving coil.

11. An electronic device adapted to the display of claim 1, comprising
a transparent layer;
a displaying layer attached to the transparent layer of the electronic device;
a receiving module, comprising:
a receiving coil; and
a shielding layer shielding the receiving coil, causing the receiving coil to be sandwiched between the shielding layer of the electronic device and the displaying layer of the electronic device,
wherein the receiving coil is configured for receiving electromagnetic wave from the transmitting coil of the display and charging the electronic device.

12. The electronic device of claim 11, wherein the receiving coil is attached to the displaying layer of the electronic device by electroplating or soldering.

13. The electronic device of claim 11, wherein the shielding layer of the electronic device is a flexible board, a size of a periphery of the receiving coil is less than that of the shielding layer of the electronic device.

14. The electronic device of claim 11, wherein the receiving coil comprises many turns of windings, and an outer contour of the receiving coil is substantially a “ [symbol] ” shape, the shielding layer of the electronic device is substantially in a “ [symbol] ” shape corresponding to the receiving coil and covers the receiving coil.

15. The electronic device of claim 11, wherein the receiving coil is equipped with a flexible printed circuit connecting pin, the displaying layer of the electronic device is equipped with a circuit connecting pin electrically coupled to the flexible printed circuit connecting pin of the receiving coil.
